(19) United States
(12) Patent Application Publication
(10) Pub. No.: US 2009/0121356 A1
(43) Pub. Date: May 14, 2009

(54) SEMICONDUCTOR DEVICE AND METHOD OF MANUFACTURING SEMICONDUCTOR DEVICE

(75) Inventor: Ryosuke NAKAGAWA, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/269,349

(22) Filed: Nov. 12, 2008

(30) Foreign Application Priority Data
Nov. 12, 2007 (JP) 2007-293430
Nov. 12, 2007 (JP) 2007-293431

(51) Int. Cl. H01L 23/532; H01L 21/4763

(52) U.S. Cl. 257/751; 438/627; 257/E23.161

(57) ABSTRACT

The semiconductor device according to the present invention includes a first interlayer dielectric film, a plurality of copper damascene wires embedded in the first interlayer dielectric film at an interval from each other, and a diffusion preventing film stacked on the first interlayer dielectric film for preventing diffusion of copper contained in the copper damascene wires, while an air gap closed with the diffusion preventing film is formed between the copper damascene wires adjacent to each other by partially removing the first interlayer dielectric film from the space between these copper damascene wires.

### BACKGROUND OF THE INVENTION

1. Field of the Invention

The present invention relates to a semiconductor device having copper wires (copper damascene wires) formed by the damascene process and a method of manufacturing the same.

2. Description of Related Art

The damascene process is generally known as a technique for forming copper wires.

FIG. 9 is a schematic sectional view showing the structure of a conventional semiconductor device having copper wires (copper damascene wires) formed by the damascene process.

A first interlayer dielectric film 102 is stacked on a semiconductor substrate (not shown) forming a base of a semiconductor device 101. A plurality of trenches 103 are formed in the first interlayer dielectric film 102 at intervals in the horizontal direction in FIG. 9. The trenches 103 extend in a direction orthogonal to a plane of FIG. 9.

Inner surfaces of the trenches 103 are covered with barrier films 104. Copper damascene wires 105 are embedded in the barrier films 104 by the damascene process. Surfaces of the copper damascene wires 105 are generally flush with a surface of the first interlayer dielectric film 102.

A diffusion preventing film 106 for preventing diffusion of copper from the copper damascene wires 105 is stacked on the surfaces of the first interlayer dielectric film 102 and the copper damascene wires 105. A second interlayer dielectric film 107 is stacked on the diffusion preventing film 106. A trench 108 is dug in the second interlayer dielectric film 107 from the surface thereof. A bottom portion of the trench 108 is positioned on an intermediate portion of the second interlayer dielectric film 107 in the thickness direction. A barrier film 110 is formed on an inner surface of the trench 108. A copper damascene wire 111 is embedded in the barrier film 110 by the damascene process. A via hole 109 is formed in the portion where the copper damascene wire 111 and the corresponding copper damascene wire 105 are vertically opposed to each other, to pass through the second interlayer dielectric film 107. A via made of copper is embedded in the via hole 109 through the barrier film 110. Thus, the copper damascene wires 105 and 111 are electrically connected with each other through the via.

As the semiconductor device 101 is scaled down, intervals between the copper damascene wires 105 are reduced (refer to US 2006/0281298A1).

If the intervals between the copper damascene wires 105 are reduced, however, a capacitance (interwire capacitance) between each pair of adjacent copper damascene wires 105 may increase, to cause a signal delay.

### SUMMARY OF THE INVENTION

An object of the present invention is to provide a semiconductor device capable of reducing a capacitance between copper damascene wires and a method of manufacturing the same.

A semiconductor device according to the present invention includes a first interlayer dielectric film, a plurality of copper damascene wires embedded in the first interlayer dielectric film at an interval from each other, and a diffusion preventing film stacked on the first interlayer dielectric film for preventing diffusion of copper contained in the copper damascene wires, while an air gap closed with the diffusion preventing film is formed between the copper damascene wires adjacent to each other by partially removing the first interlayer dielectric film from the space between these copper damascene wires.

According to this structure, the plurality of copper damascene wires are embedded in the first interlayer dielectric film at the interval. The diffusion preventing film for preventing diffusion of copper is stacked on the first interlayer dielectric film. The air gap closed with the diffusion preventing film is formed by partially removing the first interlayer dielectric film from the space between the copper damascene wires adjacent to each other. The air gap is so formed between the adjacent copper damascene wires that the interwire capacitance between these copper damascene wires can be reduced.

Preferably, the air gap is formed between the copper damascene wires adjacent to each other at an interval of not more than a prescribed interval. According to this structure, the air gap closed with the diffusion preventing film is formed by partially removing the first interlayer dielectric film from the space between the copper damascene wires adjacent to each other at the interval of not more than the prescribed interval. In other words, the air gap is not formed between copper damascene wires adjacent to each other at an interval greater than the prescribed interval. While the mechanical strength of the interconnection structure may be reduced if the air gap is randomly formed between the copper damascene wires, such reduction in the mechanical strength of the interconnection structure resulting from formation of the air gap can be prevented by properly setting the interval between the copper damascene wires.

A through-hole may be formed in the diffusion preventing film on a portion facing the air gap.

Preferably, a support portion supporting the diffusion preventing film is formed in the space between the copper damascene wires provided with the air gap by selectively leaving the first interlayer dielectric film in the space between the copper damascene wires. According to this structure, the support portion is formed between the copper damascene wires by selectively leaving the first interlayer dielectric film. Thus, the support strength for the diffusion preventing film can be increased, and reduction in the mechanical strength of the interconnection structure can be further prevented.

When the semiconductor device further includes a second interlayer dielectric film stacked on the diffusion preventing film and a via passing through the diffusion preventing film and the second interlayer dielectric film to be connected to the copper damascene wire adjacent to the air gap, the support portion is preferably formed adjacently to the side provided with the air gap with respect to a connecting position for the via in the copper damascene wire.

The via connected to the copper damascene wire is formed by forming a via hole passing through the second interlayer dielectric film and the diffusion preventing film on the copper damascene wire and deposition-growing copper in the via hole, for example. If the air gap is formed adjacently to the position where the via is connected the copper damascene wire, for example, the lower end of the via hole opens with respect to the air gap and a film serving as a seed film for the deposition growth is partitioned on a communicating portion when misalignment is caused between the position where the via hole is formed and the copper damascene wire, and hence copper may not be deposition-grown in the via hole. In this case, the via cannot be formed, and hence defective connection is caused between the copper damascene wires in the stacking direction.

When the support portion is formed adjacently to the connecting position for the via in the copper damascene wire, the support portion closes the lower end of the via hole even if misalignment is caused between the position where the via hole is formed and the copper damascene wire. Therefore, the film serving as the seed film can be excellently formed on the inner surface of the via hole, and copper can be excellently deposition-grown in the via hole. Consequently, the via can be excellently formed, to reliably attain the electrical connection.

Preferably, a plurality of support portions are formed at an interval in a direction along the copper damascene wires. According to this structure, the plurality of support portions are so dispersively provided that the same can support the diffusion preventing film in a well-balanced manner.

A method of manufacturing a semiconductor device according to the present invention includes the steps of embedding a plurality of copper damascene wires in an interlayer dielectric film by the damascene process, selectively removing the interlayer dielectric film from the space between the copper damascene wires adjacent to each other by wet etching, and forming a diffusion preventing film for preventing diffusion of copper contained in the copper damascene wires on the interlayer dielectric film to cover the surfaces of the copper damascene wires while closing a portion from which the interlayer dielectric film is selectively removed so that an air gap is formed in this portion. According to this method, a semiconductor device having an air gap formed between copper damascene wires adjacent to each other can be obtained.

Another method of manufacturing a semiconductor device according to the present invention includes the steps of embedding a plurality of copper damascene wires in an interlayer dielectric film by the damascene process, forming a diffusion preventing film covering the surfaces of the damascene wires for preventing diffusion of copper contained in the copper damascene wires on the interlayer dielectric film, forming a through-hole in the diffusion preventing film above the space between the copper damascene wires adjacent to each other by dry etching, and supplying an etching solution to a portion of the interlayer dielectric film located between the copper damascene wires through the through-hole for selectively removing the interlayer dielectric film from the space between the copper damascene wires and forming an air gap in a portion from which the interlayer dielectric film is selectively removed. According to this method, a semiconductor device having an air gap formed between copper damascene wires adjacent to each other can be obtained. The through-hole is formed in the diffusion preventing film above the space between the copper damascene wires. The etching solution is supplied to the interlayer dielectric film through the through-hole. Therefore, the etching solution does not come into contact with the surfaces of the copper damascene wires at the time of wet etching. Therefore, the surfaces of the copper damascene wires can be prevented from oxidation.

The foregoing and other objects, features and effects of the present invention will become more apparent from the following detailed description of the embodiments with reference to the attached drawings.

### BRIEF DESCRIPTION OF THE DRAWINGS

FIG. 1 is a sectional view schematically showing the structure of a semiconductor device according to an embodiment of the present invention;

FIG. 2 is a sectional view of the semiconductor device taken along the line II-II in FIG. 1;

FIG. 3 is a sectional view of the semiconductor device taken along the line III-III in FIG. 2;

FIG. 4A is a schematic sectional view showing a method of manufacturing the semiconductor device shown in FIG. 1;

FIG. 4B is a schematic sectional view successively showing a step of FIG. 4A;

FIG. 4C is a schematic sectional view successively showing a step of FIG. 4B;

FIG. 4D is a schematic sectional view successively showing a step of FIG. 4C;

FIG. 4E is a schematic sectional view successively showing a step of FIG. 4D;

FIG. 4F is a schematic sectional view successively showing a step of FIG. 4E;

FIG. 4G is a schematic sectional view successively showing a step of FIG. 4F;

FIG. 4H is a schematic sectional view successively showing a step of FIG. 4G;

FIG. 4I is a schematic sectional view successively showing a step of FIG. 4H;

FIG. 4J is a schematic sectional view successively showing a step of FIG. 4I;

FIG. 4K is a schematic sectional view successively showing a step of FIG. 4J;

FIG. 4L is a schematic sectional view successively showing a step of FIG. 4K;

FIG. 5 is a sectional view schematically showing the structure of a semiconductor device according to another embodiment of the present invention;

FIG. 6 is a sectional view of the semiconductor device taken along the line VI-VI in FIG. 5;

FIG. 7 is a sectional view of the semiconductor device taken along the line VII-VII in FIG. 6;

FIG. 8A is a schematic sectional view showing a method of manufacturing the semiconductor device show in FIG. 5;

FIG. 8B is a schematic sectional view successively showing a step of manufacturing the semiconductor device show in FIG. 8A;

FIG. 8C is a schematic sectional view successively showing a step of manufacturing the semiconductor device show in FIG. 8B;

FIG. 8D is a schematic sectional view successively showing a step of manufacturing the semiconductor device show in FIG. 8C;

FIG. 8E is a schematic sectional view successively showing a step of manufacturing the semiconductor device show in FIG. 8D;

FIG. 8F is a schematic sectional view successively showing a step of manufacturing the semiconductor device show in FIG. 8E;

FIG. 8G is a schematic sectional view successively showing a step of manufacturing the semiconductor device show in FIG. 8F;

FIG. 8H is a schematic sectional view successively showing a step of manufacturing the semiconductor device show in FIG. 8G;

FIG. 8I is a schematic sectional view successively showing a step of manufacturing the semiconductor device show in FIG. 8H;

FIG. 8J is a schematic sectional view successively showing a step of manufacturing the semiconductor device show in FIG. 8I;

FIG. 8K is a schematic sectional view successively showing a step of manufacturing the semiconductor device show in FIG. 8J;

FIG. 8L is a schematic sectional view successively showing a step of manufacturing the semiconductor device show in FIG. 8K;

FIG. 8M is a schematic sectional view successively showing a step of manufacturing the semiconductor device show in FIG. 8L; and

FIG. 9 is a schematic sectional view of a conventional semiconductor device having copper damascene wires.

### DETAILED DESCRIPTION OF PREFERRED EMBODIMENTS

Embodiments of the present invention are now described in detail with reference to the attached drawings.

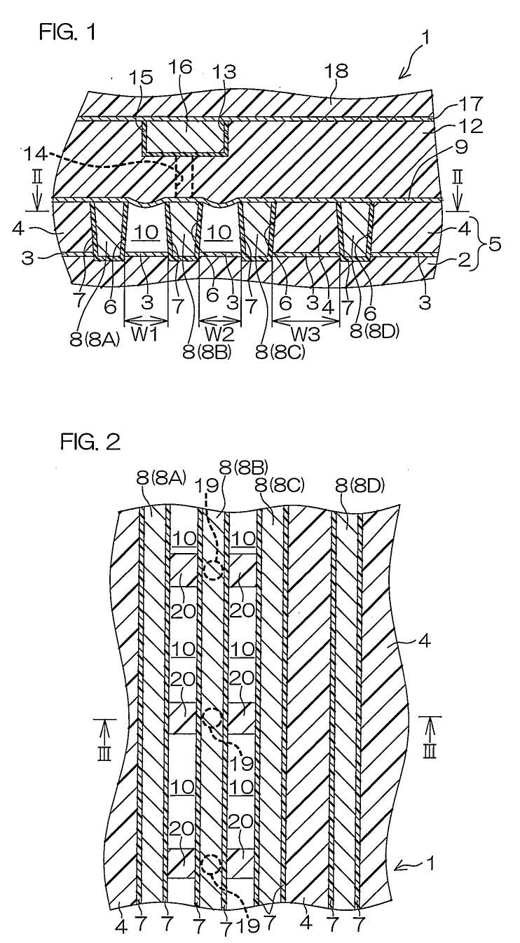

FIG. 1 is a sectional view schematically showing the structure of a semiconductor device 1 according to an embodiment of the present invention.

The semiconductor device 1 has a multilayer interconnection structure (consisting of two layers in this embodiment) of copper damascene wires 8 and 16 formed by the damascene process.

A lower insulating layer 2 made of SiO₂ is stacked on a semiconductor substrate (not shown) forming a base of the semiconductor device 1. An etching stopper film 3 made of SiN (silicon nitride) is formed on a surface of the lower insulating layer 2. An upper insulating layer 4 made of SiO₂ is stacked on the etching stopper film 3. The lower insulating layer 2 and the upper insulating layer 4 are vertically separated from each other by the etching stopper film 3, and constitute a first interlayer dielectric film 5.

Wiring trenches 6 are dug in the upper insulating layer 4 from the surface thereof. The wiring trenches 6 pass through the upper insulating layer 4 and the etching stopper film 3, so that the deepest portions thereof reach the lower insulating layer 2. A plurality of wiring trenches 6 are formed at intervals in the horizontal direction in FIG. 1, to extend in a direction orthogonal to a plane of FIG. 1 respectively.

Barrier films 7 made of TaN (tantalum nitride) are formed in the wiring trenches 6, to cover the overall inner surfaces thereof. In the wiring trenches 6, copper damascene lower wires 8 are embedded inside the barrier films 7. Surfaces of the copper damascene lower wires 8 are generally flush with a surface of the upper insulating layer 4. The copper damascene lower wires 8 are electrically connected to the semiconductor substrate.

In the four copper damascene lower wires 8 shown in FIG. 1, wires 8A, 8B, 8C and 8D are generally identical in width (80 to 90 nm, for example) to one another.

The interval W1 between the wires 8A and 8B is set to about 80 to 90 nm, for example. The interval W2 between the wires 8B and 8C is also set to about 80 to 90 nm, for example. The interval W3 between the wires 8C and 8D is set to a value (about 200 nm, for example) greater than the intervals W1 and W2. A plurality of air gaps 10 are formed between the wires 8A and 8B and between the wires 8B and 8C respectively. The air gaps 10 reduce the interwire capacitances between the wires 8A and 8B and between the wires 8B and 8C respectively.

A diffusion preventing film 9 made of SiN is formed on the surfaces of the upper insulating layer 4 and the copper damascene lower wires 8. This diffusion preventing film 9 prevents diffusion of copper from the copper damascene lower wires 8.

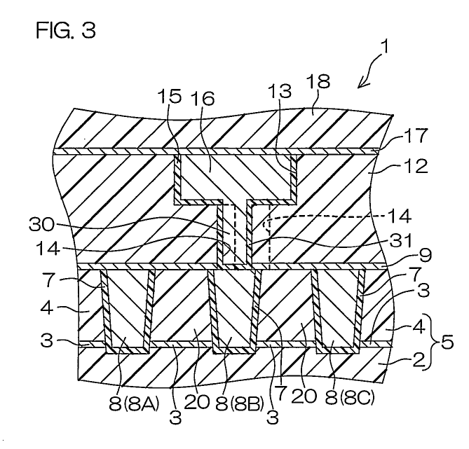

A second interlayer dielectric film 12 made of SiO₂ is stacked on the diffusion preventing film 9. A wiring trench 13 is dug in the second interlayer dielectric film 12 from the surface thereof. The bottom surface of the wiring trench 13 is positioned on an intermediate portion of the second interlayer dielectric film 12 in the thickness direction. A via hole 14 connecting the bottom surface of the wiring trench 13 and the surface of the corresponding copper damascene lower wire 8 is formed in the second interlayer dielectric film 12. A barrier film 15 made of TaN is formed in the wiring trench 13, to cover the overall inner surface thereof. In the wiring trench 13, a copper damascene upper wire 16 is embedded inside the barrier film 15. A via 30 (see FIG. 3) is embedded in the via hole 14, as described later. The via 30 is connected to the corresponding copper damascene lower wire 8 on a via connecting position 19 (see FIGS. 2 and 3). Thus, the copper damascene upper wire 16 is electrically connected with the corresponding copper damascene lower wire 8.

A diffusion preventing film 17 for preventing diffusion of copper contained in the copper damascene upper wire 16 is stacked on the second interlayer dielectric film 12 and the copper damascene upper wire 16. A third interlayer dielectric film 18 made of SiO₂ is stacked on the diffusion preventing film 17.

FIG. 2 is a sectional view of the semiconductor device 1 taken along the line II-II in FIG. 1.

A plurality of support films 20 as support portions for supporting the diffusion preventing film 9 are formed between the wires 8A and 8B at prescribed intervals in a direction along the wires 8A and 8B. Also between the wires 8B and 8C, a plurality of support films 20 for supporting the diffusion preventing film 9 are formed at prescribed intervals in the direction along the wires 8A and 8B.

Each support film 20 is provided adjacently to the via connecting position 19 in the corresponding copper damascene lower wire 8. In other words, the support films 20 are formed on both sides of the via connecting position 19 in each copper damascene lower wire 8.

FIG. 3 is a sectional view of the semiconductor device 1 taken along the line III-III in FIG. 2.

A barrier film 31 made of TaN is formed in the via hole 14, to cover the overall regions of the side surface and the bottom surface of the via hole 14. In the via hole 14, the via 30 is embedded inside the barrier film 31.

The support films 20 are formed adjacently to the via connecting position 19, whereby the connecting port of the via hole 14 is covered and closed with the surface of either one of the support films 20 even if misalignment is caused between the position where the via hole 14 is formed and the corresponding copper damascene lower wire 8 as shown by broken lines in FIG. 3.

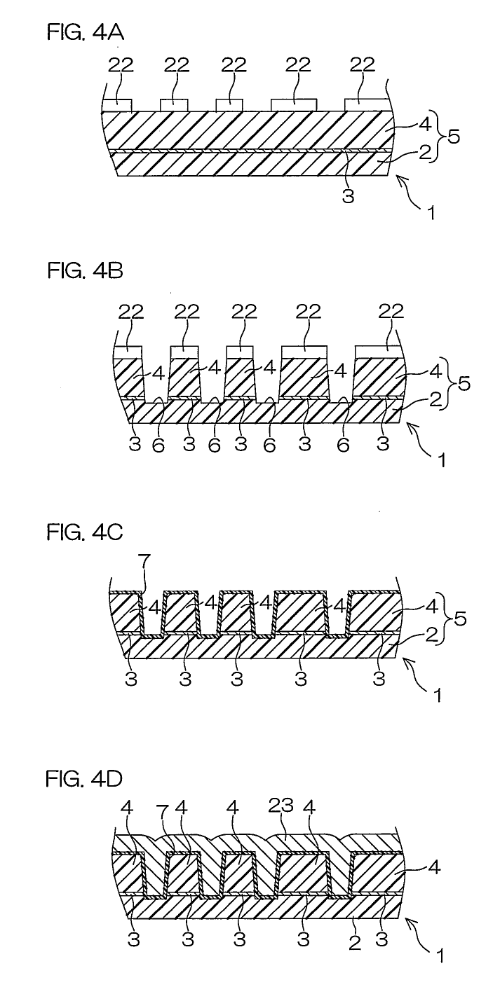

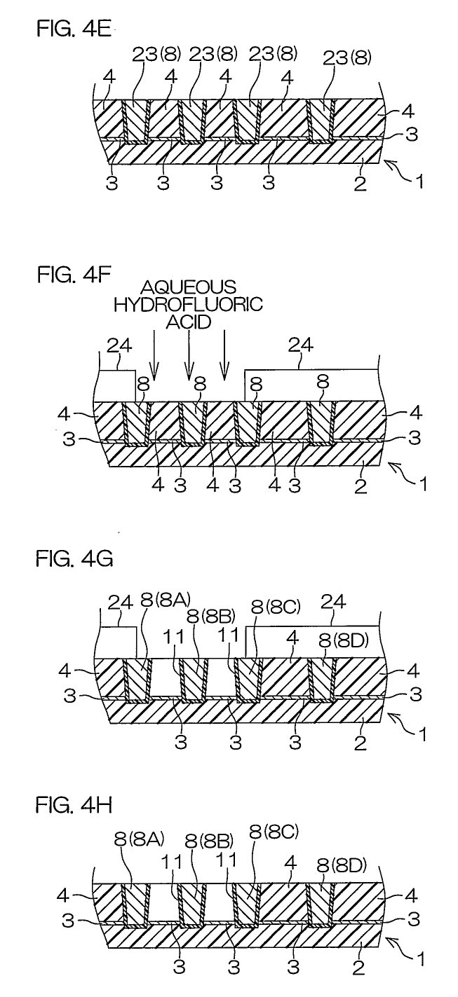

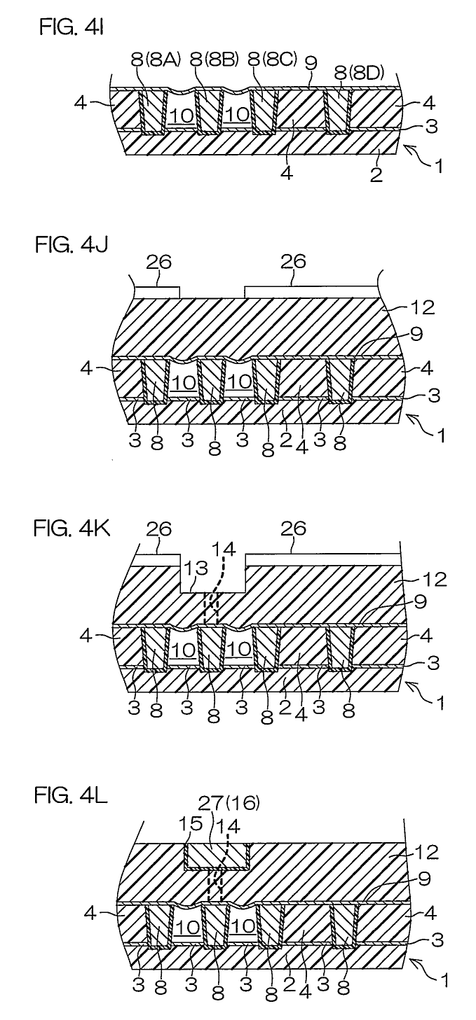

FIGS. 4A to 4L are schematic sectional views successively showing the steps of manufacturing the semiconductor device 1.

First, the first interlayer dielectric film 5 is formed on the semiconductor substrate (not shown) by CVD, as shown in FIG. 4A. Thereafter a mask 22 of a pattern having openings in portions opposed to those for forming the wiring trenches 6 is formed on the surface of the first interlayer dielectric film 5.

Thereafter the wiring trenches 6 are formed in the interlayer dielectric film 5 by etching through the mask 22, as shown in FIG. 4B. Thereafter the mask 22 is removed, whereby the surface of the upper insulating layer 4 is exposed.

Then, a barrier film 7 made of TaN is formed on the upper surface of the first interlayer dielectric film 5 and the inner surfaces of the wiring trenches 6 by sputtering, as shown in FIG. 4C.

Thereafter a copper film 23 is formed on the barrier film 7 by deposition growth. The copper film 23 filling up the wiring trenches 6 is formed also on portions of the upper insulating layer 4 located outside the wiring trenches 6, as shown in FIG. 4D.

Then, the portions of the copper film 23 located outside the wiring trenches 6 are removed by CMP technique, as shown in FIG. 4E. Consequently, the surfaces of the remaining portions of the copper film 23 are planarized to be generally flush with the surface of the upper insulating layer 4. Thus, the copper damascene lower wires 8 are formed.

Then, a resist film 24 is formed on the surfaces of the upper insulating layer 4 and the copper damascene lower wires 8. As shown in FIG. 4F, the resist film 24 is formed by photolithography technique and etching technique, in a pattern having openings in portions opposed to those for forming the air gaps 10. In other words, the resist film 24 is partially provided with openings above the regions held between the wires 8A and 8B and between the wires 8B and 8C respectively.

Then, an etching solution such as aqueous hydrofluoric acid is supplied to the surfaces of the upper insulating layer 4 and the copper damascene lower wires 8 through the openings of the resist film 24 (wet etching). Thus, the upper insulating layer 4 is selectively removed from the portions for forming the air gaps 10, and air gap trenches 11 are formed as a result, as shown in FIG. 4G. The air gap trenches 11 are partitioned by the pairs of copper damascene lower wires 8 adjacent to one another and the etching stopper film 3. On the other hand, portions of the upper insulating layer 4 to be provided with no air gaps 10 are covered with the resist film 24 and selectively left. Thus, the support films 20 (see FIG. 2) are formed. Thereafter the resist film 24 is removed, as shown in FIG. 4H.

The surfaces of the copper damascene lower wires 8 may be oxidized by the etching solution coming into contact therewith in the wet etching step. In this case, hydrogen-containing gas is preferably supplied to the surfaces of the copper damascene lower wires 8 after the wet etching step, to reduce the surfaces of the copper damascene lower wires 8.

Then, the diffusion preventing film 9 is formed on the surfaces of the upper insulating layer 4 and the copper damascene lower wires 8 by CVD, as shown in FIG. 4I. At this time, the film forming conditions are so set as to deteriorate step coverage. Thus, the diffusion preventing film 9 extends between the copper damascene lower wires 8 provided on both sides of each air gap trench 11 above the air gap trench 11. This diffusion preventing film 9 closes the air gap trenches 11, thereby forming the air gaps 10.

Then, the second interlayer dielectric film 12 is formed on the diffusion preventing film 9 by CVD, as shown in FIG. 4J. A mask 26 of a pattern having an opening in a portion opposed to that for forming the wiring trench 13 is formed on the surface of the second interlayer dielectric film 12.

Thereafter the wiring trench 13 is formed by partially removing the second interlayer dielectric film 12 by etching technique through the mask 26, as shown in FIG. 4K. A prescribed pattern is formed on the etching stopper film 3 (not shown) embedded in the second interlayer dielectric film 12, so that the second interlayer dielectric film 12 and the diffusion preventing film 9 are partially removed from the portion for forming the via 30. Thus, the via hole 14 is formed simultaneously with the formation of the wiring trench 13.

Thereafter the mask 26 is removed, whereby the surface of the second interlayer dielectric film 12 is exposed. Then, the barrier films 15 and 31 are formed on the upper surface of the second interlayer dielectric film 12, the side surface of the wiring trench 13 and the inner surfaces (the side surface and the bottom surface) of the via hole 14 by sputtering, as shown in FIG. 4L. At this time, the bottom surface of the via hole 14 is closed with at least either the surface of the corresponding copper damascene wire 8 or the corresponding support film 20. Thus, films serving as seed films can be excellently formed on the inner surfaces of the via hole 14.

Then, a copper film 27 is formed on the barrier films 15 and 31 by deposition growth. The barrier films 15 and 31 serving as the seed films are excellently formed on the overall regions of the inner surfaces of the wiring trench 13 and the via hole 14, whereby the copper film 27 is excellently deposition-grown.

The copper film 27 filling up the wiring trench 13 and the via hole 14 is formed also on the portions of the second interlayer dielectric film 12 located outside the wiring trench 13. Thereafter the portions of the copper film 27 located outside the wiring trench 13 are removed by CMP technique. Consequently, the surface of the remaining portion of the copper film 27 is planarized to be generally flush with the surface of the second interlayer dielectric film 12, thereby forming the copper damascene upper wire 16. Further, the via 30 (see FIG. 3) for electrically connecting the corresponding copper damascene lower wire 8 and the copper damascene upper wire 16 with each other is formed in the via hole 14.

After the aforementioned steps, the diffusion preventing film 17 is formed on the surfaces of the second interlayer dielectric film 12 and the copper damascene upper wire 16 by P-CVD. Thereafter the third interlayer dielectric film 18 is formed on the diffusion preventing film 17 by CVD. The multilayer interconnection structure shown in FIG. 1 is formed on the semiconductor substrate due to the aforementioned steps. Thus, the semiconductor device 1 is obtained.

According to this embodiment, the plurality of copper damascene lower wires 8 are embedded in the first interlayer dielectric film 5 at the intervals. The diffusion preventing film 9 for preventing diffusion of copper is stacked on the first interlayer dielectric film 5. The air gaps 10 closed with the diffusion preventing film 9 are formed by partially removing the first interlayer dielectric film 5 from the spaces between the copper damascene lower wires 8A and 8B and between the copper damascene lower wires 8B and 8C adjacent to one another at the relatively small interval W1 (W2) respectively. In other words, no air gap 10 is formed between the copper damascene lower wires 8C and 8D adjacent to each other at the relatively large interval W3. Therefore, reduction in the mechanical strength of the interconnection structure resulting from formation of the air gaps 10 can be prevented. On the other hand, the air gaps 10 are so formed between the copper damascene lower wires 8A and 8B and between the copper damascene lower wires 8B and 8C adjacent to one another at the relatively small interval W1 (W2), that the interwire capacitances between the copper damascene lower wires 8A and 8B and between the copper damascene lower wires 8B and 8C can be reduced.

The support films 20 are formed between the copper damascene lower wires 8 by selectively leaving the first interlayer dielectric film 5. Thus, support strength for the diffusion preventing film 9 can be increased, and reduction in the mechanical strength of the interconnection structure can be further prevented. Further, the plurality of support films 20 are so dispersively provided that the same can support the diffusion preventing film 9 in a well-balanced manner.

The via 30 connected to the corresponding copper damascene lower wire 8 is formed by forming the via hole 14 passing through the second interlayer dielectric film 12 and the diffusion preventing film 9 on the corresponding copper damascene lower wire 8 and deposition-growing copper in this via hole 14, for example.

Therefore, the support films 20 are formed adjacently to the via connecting position 19 in the corresponding copper damascene lower wire 8, whereby the lower end of the via hole 14 is closed with either one of the support films 20 even if misalignment is caused between the position where the via hole 14 is formed and the corresponding copper damascene lower wire 8. Thus, the barrier film 31 serving as the seed film can be excellently formed on the inner surface of the via hole 14, and copper can be excellently deposition-grown in the via hole 14. Consequently, the via 30 can be excellently formed, and the electrical connection can be reliably attained.

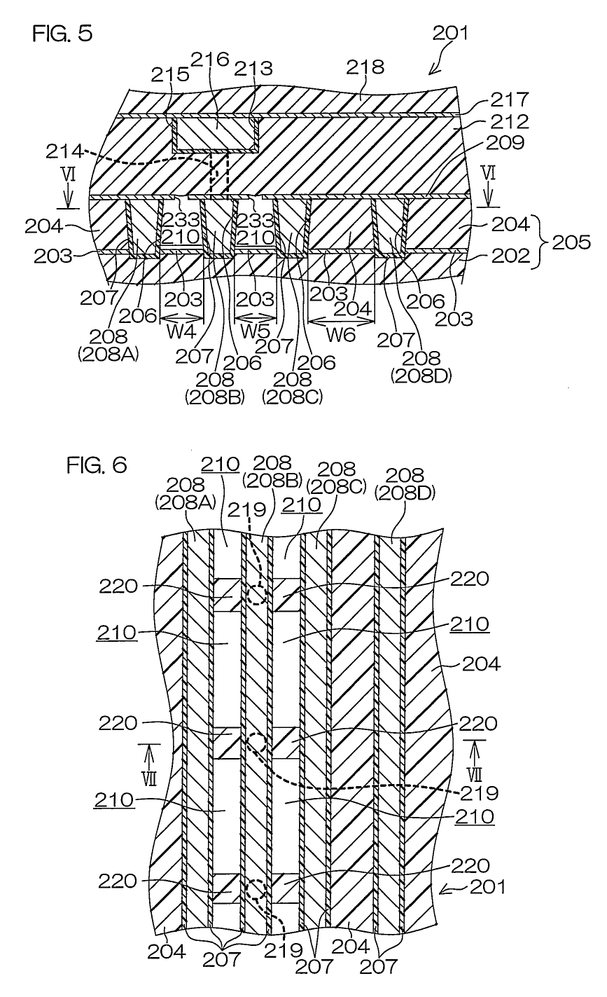

FIG. 5 is a sectional view schematically showing the structure of a semiconductor device 201 according to another embodiment of the present invention.

The semiconductor device 201 has a multilayer interconnection structure (consisting of two layers in this embodiment) of copper damascene wires 208 and 216 formed by the damascene process.

A lower insulating layer 202 made of SiO₂ is stacked on a semiconductor substrate (not shown) forming a base of the semiconductor device 201. An etching stopper film 203 made of SiN is formed on the surface of the lower insulating layer 202. An upper insulating layer 204 made of SiO₂ is stacked on the etching stopper film 203. The lower insulating layer 202 and the upper insulating layer 204 are vertically separated from each other by the etching stopper film 203, and constitute a first interlayer dielectric film 205.

Wiring trenches 206 are dug in the upper insulating layer 204 from the surface thereof. The wiring trenches 206 pass through the upper insulating layer 204 and the etching stopper film 203, so that the deepest portions thereof reach the lower insulating layer 202. The plurality of wiring trenches 206 are formed at intervals in the horizontal direction in FIG. 5, to extend in a direction orthogonal to the plane of FIG. 5 respectively.

Barrier films 207 made of TaN are formed in the wiring trenches 206, to cover the overall inner surfaces thereof. In the wiring trenches 206, copper damascene lower wires 208 are embedded inside the barrier films 207. The surfaces of the copper damascene lower wires 208 are generally flush with the surface of the upper insulating layer 204. The copper damascene lower wires 208 are electrically connected to the semiconductor substrate.

In the four copper damascene lower wires 208 shown in FIG. 5, wires 208A, 208B, 208C and 208D are generally identical in width (80 to 90 nm, for example) to one another.

The interval W4 between the wires 208A and 208B is set to about 80 to 90 nm, for example. The interval W5 between the wires 208B and 208C is also set to about 80 to 90 nm, for example. The interval W6 between the wires 208C and 208D is set to a value (about 200 nm, for example) greater than the intervals W4 and W5. A plurality of air gaps 210 are formed between the wires 208A and 208B and between the wires 208B and 208C respectively. The air gaps 210 reduce the interwire capacitances between the wires 208A and 208B and between the wires 208B and 208C respectively.

A diffusion preventing film 209 made of SiN is formed on the surfaces of the upper insulating layer 204 and the copper damascene lower wires 208. This diffusion preventing film 209 prevents diffusion of copper from the copper damascene lower wires 208. In the diffusion preventing film 209, through-holes 233 are formed on portions facing the air gaps 210 respectively. Each through-hole 233 is a round hole having a small diameter of 60 nm, for example.

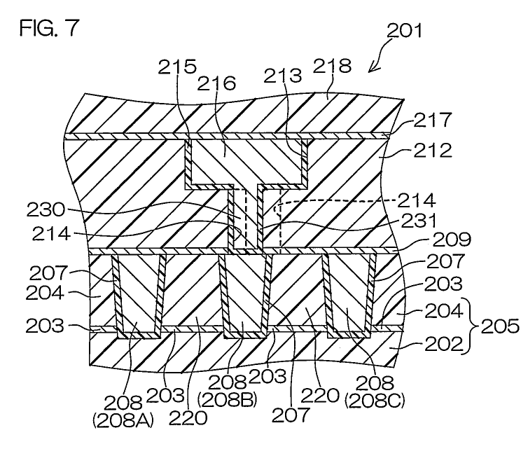

A second interlayer dielectric film 212 made of SiO₂ is stacked the diffusion preventing film 209. A wiring trench 213 is dug in the second interlayer dielectric film 212 from the surface thereof. The bottom surface of the wiring trench 213 is positioned on an intermediate portion of the second interlayer dielectric film 212 in the thickness direction. A via hole 214 connecting the bottom surface of the wiring trench 213 and the surface of the corresponding copper damascene lower wire 208 with each other is formed in the second interlayer dielectric film 212. A barrier film 215 made of TaN is formed in the wiring trench 213, to cover the overall inner surface thereof. In the wiring trench 213, a copper damascene upper wire 216 is embedded inside the barrier film 215. A via 230 (see FIG. 7) is embedded in the via hole 214, as described later. The via 230 is connected to the corresponding copper damascene lower wire 208 on a via connecting position 219 (see FIGS. 6 and 7). Thus, the copper damascene upper wire 216 is electrically connected with the corresponding copper damascene lower wire 208.

A diffusion preventing film 217 for preventing diffusion of copper contained in the copper damascene upper wire 216 is stacked on the second interlayer dielectric film 212 and the copper damascene upper wire 216. A third interlayer dielectric film 218 made of SiO₂ is stacked on the diffusion preventing film 217.

FIG. 6 is a sectional view of the semiconductor device 201 taken along the line VI-VI in FIG. 5.

A plurality of support films 220 as support portions for supporting the diffusion preventing film 209 are formed between the wires 208A and 208B at prescribed intervals in a direction along the wires 208A and 208B. Also between the wires 208B and 208C, a plurality of support films 220 for supporting the diffusion preventing film 209 are formed at prescribed intervals in the direction along the wires 208A and 208B.

Each support film 220 is provided adjacently to the via connecting position 219 in the corresponding copper damascene lower wire 208. In other words, the support films 220 are formed on both sides of the via connecting position 219 in each copper damascene lower wire 208.

FIG. 7 is a sectional view of the semiconductor device 201 taken along the line VII-VII in FIG. 6.

A barrier film 231 made of TaN is formed in the via hole 214, to cover the overall regions of the side surface and the bottom surface of the via hole 214. In the via hole 214, the via 230 is embedded inside the barrier film 231.

The support films 220 are formed adjacently to the via connecting position 219, whereby the connecting port of the via hole 214 is covered and closed with the surface of either one of the support films 220 even if misalignment is caused between the position where the via hole 214 is formed and the corresponding copper damascene lower wire 208 as shown by broken lines in FIG. 7.

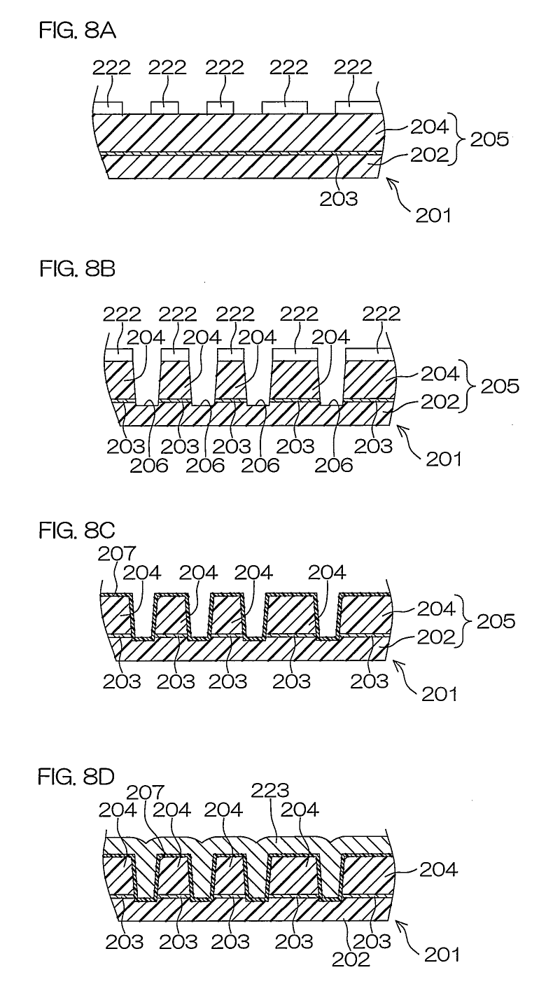

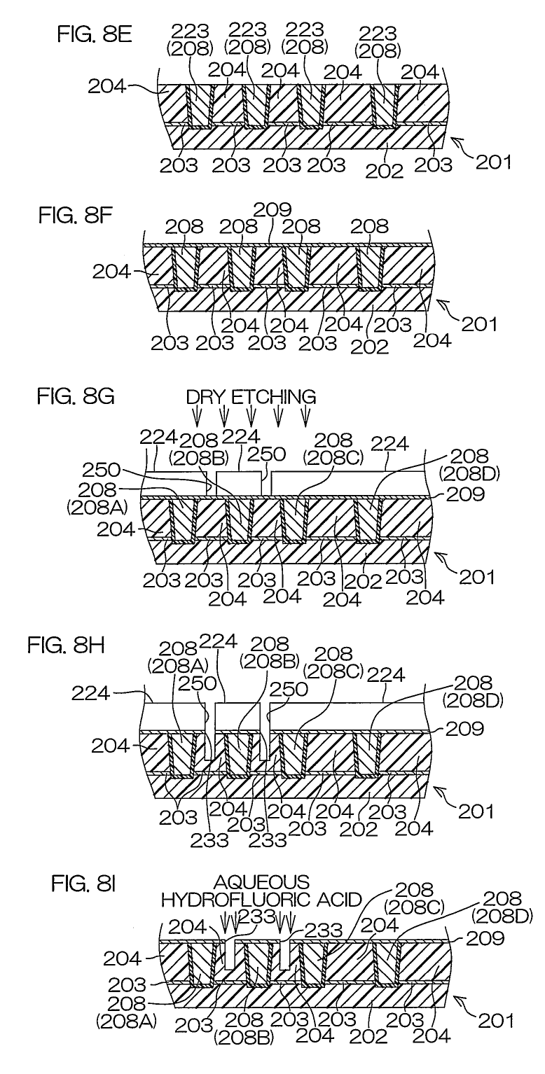

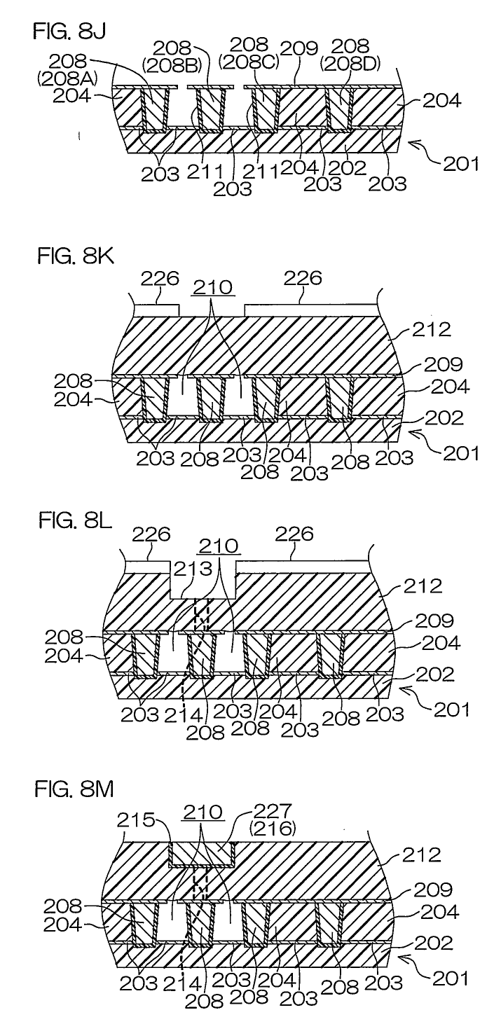

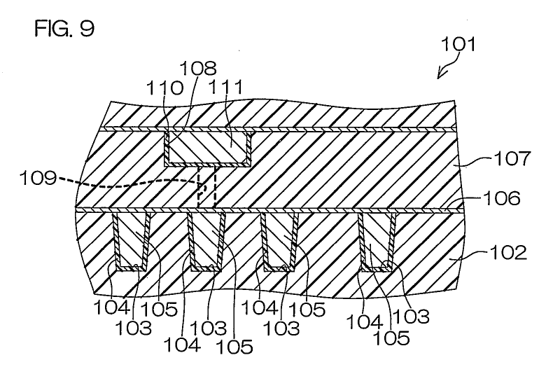

FIGS. 8A to 8M are schematic sectional views successively showing the steps of manufacturing the semiconductor device 201.

First, the first interlayer dielectric film 205 is formed on the semiconductor substrate (not shown) by CVD, as shown in FIG. 8A. Thereafter a mask 222 of a pattern having openings in portions opposed to those for forming the wiring trenches 206 is formed on the surface of the first interlayer dielectric film 205.

Thereafter the wiring trenches 206 are formed in the first interlayer dielectric film 205 by etching technique through the mask 222, as shown in FIG. 8B. Thereafter the mask 222 is removed, whereby the surface of the upper insulating layer 204 is exposed.

Then, a barrier film 207 made of TaN is formed on the upper surface of the first interlayer dielectric film 205 and the inner surfaces of the wiring trenches 206 by sputtering, as shown in FIG. 8C.

Thereafter a copper film 223 is formed on the barrier film 207 by deposition growth. The copper film 223 filling up the wiring trenches 206 is formed also on portions of the upper insulating layer 204 located outside the wiring trenches 206, as shown in FIG. 8D.

Then, the portions of the copper film 223 located outside the wiring trenches 206 are removed by CMP technique, as shown in FIG. 8E. Consequently, the surfaces of the remaining portions of the copper film 223 are planarized to be generally flush with the surface of the upper insulating layer 204. Thus, the copper damascene lower wires 208 are formed.

Then, the diffusion preventing film 209 is formed on the surfaces of the upper insulating layer 204 and the copper damascene lower wires 208 by CVD, as shown in FIG. 8F.

Then, a resist film 224 is formed on the surface of the diffusion preventing film 209. As shown in FIG. 8G, the resist film 224 is formed by photolithography and etching, to have round holes 250 opposed to portions for forming the air gaps 210. In other words, the resist film 224 is partially provided with the round holes 250 above regions held between the wires 208A and 208B and between the wires 208B and 208C respectively.

Then, etching gas such as CₓF_{y} gas (C₄F₈/O₂/Ar gas, for example) is supplied to the surface of the diffusion preventing film 209 through the round holes 250 of the resist film 224 (dry etching). Thus, the through-holes 233 are formed in portions of the diffusion preventing film 209 positioned above the portions for forming the air gaps 210, as shown in FIG. 8H. The through-holes 233 pass through the diffusion preventing film 209, so that the bottom portions thereof are positioned on an intermediate portion of the upper insulating layer 204 in the thickness direction. Thereafter the resist film 224 is removed, as shown in FIG. 8I.

Then, an etching solution such as aqueous hydrofluoric acid is supplied to the upper insulating layer 204 through the through-holes 233 of the diffusion preventing film 209 (wet etching). Thus, the upper insulating layer 204 is selectively removed from the portions for forming the air gaps 210, and the air gaps 210 are formed, as shown in FIG. 8J.

On the other hand, the upper surfaces of portions of the upper insulating layer 204 to be provided with no air gaps 210 are covered with the diffusion preventing film 209 made of SiN having etching resistance. Therefore, no etching solution is supplied to the portions of the upper insulating layer 204 to be provided with no air gaps 210, but the support films 220 (see FIG. 6) are formed.

The through-holes 233 are so formed in the diffusion preventing film 209 positioned on the upper insulating layer 204 that the etching solution does not come into contact with the surfaces of the copper damascene lower wires 208 in the wet etching step.

Then, the second interlayer dielectric film 212 is formed on the diffusion preventing film 209 by CVD, as shown in FIG. 8K. At this time, the film forming conditions are so set as to deteriorate step coverage. The through-holes 233 formed in the diffusion preventing film 209 are small-diametral round holes as described above, and the second interlayer dielectric film 212 is inferior in step coverage. Therefore, the second interlayer dielectric film 212 formed on the diffusion preventing film 209 remains on the diffusion preventing film 209, not to enter the air gaps 210 through the through-holes 233. Thereafter a mask 226 of a pattern having an opening in a portion opposed to that for forming the wiring trench 213 is formed on the surface of the second interlayer dielectric film 212.

Thereafter the wiring trench 213 is formed by partially removing the second interlayer dielectric film 212 by etching technique through the mask 226, as shown in FIG. 8L. A prescribed pattern is formed on the etching stopper film 213 (not shown) embedded in the second interlayer dielectric film 212, so that the second interlayer dielectric film 212 and the diffusion preventing film 209 are partially removed from the portion for forming the via 230. Thus, the via hole 214 is formed simultaneously with the formation of the wiring trench 213.

Thereafter the mask 226 is removed, whereby the surface of the second interlayer dielectric film 212 is exposed. Then, the barrier films 215 and 231 are formed on the upper surface of the second interlayer dielectric film 212, the side surface of the wiring trench 213 and the inner surfaces (the side surface and the bottom surface) of the via hole 214 by sputtering, as shown in FIG. 8M. At this time, the bottom surface of the via hole 214 is closed with at least either the surface of the corresponding copper damascene wire 208 or the corresponding support film 220. Thus, films serving as seed films can be excellently formed on the inner surfaces of the via hole 214.

Then, a copper film 227 is formed on the barrier films 215 and 231 by deposition growth. The barrier films 215 and 231 serving as the seed films are excellently formed on the overall regions of the inner surfaces of the wiring trench 213 and the via hole 214, whereby the copper film 227 is excellently deposition-grown.

The copper film 227 filling up the wiring trench 213 and the via hole 214 is formed also on the portions of the second interlayer dielectric film 212 located outside the wiring trench 213. Thereafter the portions of the copper film 227 located outside the wiring trench 213 are removed by CMP technique. Consequently, the surface of the remaining portion of the copper film 227 is planarized to be generally flush with the surface of the second interlayer dielectric film 212, thereby forming the copper damascene upper wire 216. Further, the via 230 (see FIG. 7) for electrically connecting the corresponding copper damascene lower wire 208 and the copper damascene upper wire 216 is formed in the via hole 214.

After the aforementioned steps, the diffusion preventing film 217 is formed on the surfaces of the second interlayer dielectric film 212 and the copper damascene upper wire 216 by P-CVD. Thereafter the third interlayer dielectric film 218 is formed on the diffusion preventing film 217 by CVD. The multilayer interconnection structure shown in FIG. 5 is formed on the semiconductor substrate due to the aforementioned steps. Thus, the semiconductor device 201 is obtained.

According to this embodiment, the plurality of copper damascene lower wires 208 are embedded in the first interlayer dielectric film 205 at the intervals. The diffusion preventing film 209 for preventing diffusion of copper is stacked on the first interlayer dielectric film 205. The air gaps 210 closed with the diffusion preventing film 209 are formed by partially removing the first interlayer dielectric film 205 from the spaces between the copper damascene lower wires 208A and 208B and between the copper damascene lower wires 208B and 208C adjacent to one another at the relatively small interval W4 (W5) respectively. In other words, no air gap 210 is formed between the copper damascene lower wires 208C and 208D adjacent to each other at the relatively large interval W6. Thus, reduction in the mechanical strength of the interconnection structure resulting from formation of the air gap 210 can be prevented. On the other hand, the air gaps 210 are so formed between the copper damascene lower wires 208A and 208B and between the copper damascene lower wires 208B and 208C adjacent to one another at the relatively small interval W4 (W5), that the interwire capacitances between the copper damascene lower wires 208A and 208B and between the copper damascene lower wires 208B and 208C can be reduced.

The support films 220 are formed between the copper damascene lower wires 208 by selectively leaving the first interlayer dielectric film 205. Thus, support strength for the diffusion preventing film 209 can be increased, and reduction in the mechanical strength of the interconnection structure can be further prevented. Further, the plurality of support films 220 are so dispersively provided that the same can support the diffusion preventing film 209 in a well-balanced manner.

The via 230 connected to the corresponding copper damascene lower wire 208 is formed by forming the via hole 214 passing through the second interlayer dielectric film 212 and the diffusion preventing film 209 on the corresponding copper damascene lower wire 208 and deposition-growing copper in this via hole 214, for example.

Therefore, the support films 220 are formed adjacently to the via connecting position 219 in the corresponding copper damascene lower wire 208, whereby the lower end of the via hole 214 is closed with either one of the support films 220 even if misalignment is caused between the position where the via hole 214 is formed and the corresponding copper damascene lower wire 208. Thus, the barrier film 231 serving as the seed film can be excellently formed on the inner surface of the via hole 214, and copper can be excellently deposition-grown in the via hole 214. Consequently, the via 230 can be excellently formed, and the electrical connection can be reliably attained.

Further, the through-holes 233 are formed in the diffusion preventing film 2O9 above the spaces between the copper damascene lower wires 208A and 208B and between the copper damascene lower wires 208B and 208C respectively. The etching solution is supplied to the first interlayer dielectric film 205 through the through-holes 233. Therefore, the etching solution does not come into contact with the surfaces of the copper damascene lower wires 208 in the wet etching step. Thus, the surfaces of the copper damascene lower wires 208 can be prevented from oxidation.

While the two embodiments of the present invention have been described, the present invention can also be carried out in other modes. For example, the diffusion preventing films 9 and 209 may alternatively be formed by SiC (silicon carbide) films, in place of the SiN films. Further, the etching stopper films 3 and 203 may also be formed by SiC films, in place of the SiN films.

While TaN is employed as the material for the barrier films 7, 15, 31, 207, 215 and 231, the material for the barrier films 7, 15, 31, 207, 215 and 231 may alternatively be prepared from MnₓSi_{y}O_{z} (X, Y and Z: numerals greater than zero), for example, so far as the same is a metallic material having barrier properties against diffusion of Cu.

The support films 20 and 220 may be formed not only on the positions adjacent to the via connecting positions 19 and 219 but also on positions nonadjacent to the via connecting positions 19 and 219.

Further, various design modifications can be applied in the range of the subject matter described in the scope of claims for patent.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application Nos. 2007-293430 and 2007-293431 filed in the Japanese Patent Office on Nov. 12, 2007 respectively, the disclosures of which are incorporated herein by reference in its entirety.

What is claimed is:

1. A semiconductor device comprising:
a first interlayer dielectric film;
a plurality of copper damascene wires embedded in the first interlayer dielectric film at an interval from each other; and
a diffusion preventing film stacked on the first interlayer dielectric film for preventing diffusion of copper contained in the copper damascene wires, wherein
an air gap closed with the diffusion preventing film is formed between the copper damascene wires adjacent to each other by partially removing the first interlayer dielectric film from the space between these copper damascene wires.

2. The semiconductor device according to claim 1, wherein the air gap is formed between the copper damascene wires adjacent to each other at an interval of not more than a prescribed interval.

3. The semiconductor device according to claim 1, wherein a through-hole is formed in the diffusion preventing film on a portion facing the air gap.

4. The semiconductor device according to claim 1, wherein a support portion supporting the diffusion preventing film is formed in the space between the copper damascene wires provided with the air gap by selectively leaving the first interlayer dielectric film in the space between the copper damascene wires.

5. The semiconductor device according to claim 4, further comprising:
a second interlayer dielectric film stacked on the diffusion preventing film; and
a via passing through the diffusion preventing film and the second interlayer dielectric film to be connected to the copper damascene wire adjacent to the air gap, wherein
the support portion is formed adjacently to the side provided with the air gap with respect to a connecting position for the via in the copper damascene wire.

6. The semiconductor device according to claim 4, wherein a plurality of support portions are formed at an interval in a direction along the copper damascene wires.

7. A method of manufacturing a semiconductor device, including the steps of:
embedding a plurality of copper damascene wires in an interlayer dielectric film by the damascene process;
selectively removing the interlayer dielectric film from a space between the copper damascene wires adjacent to each other by wet etching; and
forming a diffusion preventing film for preventing diffusion of copper contained in the copper damascene wires on the interlayer dielectric film to cover surfaces of the copper damascene wires while closing a portion from which the interlayer dielectric film is selectively removed so that an air gap is formed in this portion.

8. A method of manufacturing a semiconductor device, including the steps of:
embedding a plurality of copper damascene wires in an interlayer dielectric film by the damascene process;
forming a diffusion preventing film covering the surfaces of the damascene wires for preventing diffusion of copper contained in the copper damascene wires on the interlayer dielectric film;
forming a through-hole in the diffusion preventing film above a space between the copper damascene wires adjacent to each other by dry etching; and
supplying an etching solution to the portion of the interlayer dielectric film located between the copper damascene wires through the through-hole for selectively removing the interlayer dielectric film from the space between the copper damascene wires and forming an air gap in the portion from which the interlayer dielectric film is selectively removed.
